(19) United States
(12) Patent Application Publication
(10) Pub. No.: US 2025/0262709 A1
(43) Pub. Date: Aug. 21, 2025

(54) METHOD AND APPARATUS FOR SUBSTRATE NOTCH SENSING ON CMP HEAD FOR LOCAL PLANARIZATION

(71) Applicant: Applied Materials, Inc., Santa Clara, CA (US)

(72) Inventor: Balasubramaniam CJ, Tamilnadu (IN)

(21) Appl. No.: 18/442,378

(22) Filed: Feb. 15, 2024

(51) Int. Cl. B24B 37/005; B24B 37/04; B24B 37/32

(52) U.S. Cl. CPC B24B 37/005; B24B 37/042; B24B 37/32

(57) ABSTRACT

Embodiments of the disclosure provided herein include systems and methods for correcting thickness asymmetry of a substrate during chemical mechanical polishing. The system includes a carrier head with a pixel cartridge array disposed within a carrier head body and a membrane adjacent to the pixel cartridge array, a notch sensor array disposed on a carrier ring, and a controller coupled to the pixel cartridge array and the notch sensor array. The controller is configured to receive and orient a substrate such that the substrate is an oriented substrate, determine a thickness profile on the oriented substrate, position the oriented substrate in a loading position, receive the oriented substrate, and polish the oriented substrate use the pixel cartridge array. The pixel cartridge array is configured to apply pressure on a membrane of a carrier head in a chemical mechanical polishing system.

### BACKGROUND

### Field

Embodiments of the present disclosure generally relate to semiconductor manufacturing. More specifically, the embodiments of the present disclosure generally relate to correcting thickness asymmetry of a substrate during chemical mechanical polishing.

### Description of the Related Art

Chemical mechanical polishing (CMP) is commonly used in the manufacturing of high-density integrated circuits to planarize or polish a layer of material deposited on a substrate. A CMP process includes contacting the material layer to be planarized with a polishing pad and moving the polishing pad, the substrate, or both, to create relative movement between the material layer surface and the polishing pad, in the presence of a polishing fluid including abrasive particles, chemically active components, or both.

One common application of a CMP process in semiconductor device manufacturing is planarization of a bulk film, for example pre-metal dielectric (PMD) or interlayer dielectric (ILD) polishing, where underlying two or three-dimensional features create recesses and protrusions in the to be planarized material surface. This planarization method typically requires that the substrate be mounted on a carrier head. The exposed surface of the substrate, the surface with the layer deposition, is typically placed against a rotating polishing pad. The carrier head provides a controllable load on the substrate to urge it against the polishing pad. A polishing slurry with abrasive particles is typically supplied to the surface of the polishing pad and spreads in between the substrate and the polishing pad. The polishing pad and the carrier head each rotate at a constant rotational speed and the abrasive slurry removes material from one or more of the layers. Material is removed in a planar fashion and the material removal process is symmetric about a central axis. The symmetric removal process may be problematic because a substrate having an asymmetrically non-uniform thickness profile will remain asymmetric after the CMP process is complete. For example, the asymmetric thickness of the substrate may result in the circuits formed on a surface of the substrate having a different RC time constant for the integrated circuits in devices formed on opposing sides of the same surface of the substrate, due to the ICs formed on the thinner edge of the substrate having less metal than the ICs formed on the thicker edge of the substrate. The resulting integrated circuits will have processing speeds that vary based on the corresponding substrate thickness. Thus, the variance in RC time constants results in devices of varying quality, which is not desirable. Although described as on opposing sides or edges, the location of the thinnest and thickest sides or areas of the substrate may be in other locations of the substrate.

Accordingly, there is a need in the art for correcting asymmetry in substrates during chemical mechanical polishing.

### SUMMARY

Embodiments described herein generally relate to systems and methods used for correcting thickness asymmetry of a substrate during chemical mechanical polishing.

In an embodiment, a chemical mechanical polishing system is provided. The polishing system includes a carrier head including a carrier head body, a pixel cartridge array disposed within the carrier head body, and a membrane adjacent to the pixel cartridge array, a carrier ring configured to couple with the carrier head, a notch sensor array disposed on the carrier ring, and a controller coupled to the pixel cartridge array and the notch sensor array. The controller is configured to receive and orient a substrate such that the substrate is an oriented substrate, determine a thickness profile on the oriented substrate, position the oriented substrate in a loading position, receive the oriented substrate, and polish the oriented substrate use the pixel cartridge array. The pixel cartridge array is configured to apply pressure on a membrane of a carrier head in a chemical mechanical polishing system.

In another embodiment, a carrier head for chemical mechanical polishing is provided. The carrier head includes a carrier head body configured to couple with a carrier ring, a pixel cartridge array disposed within the carrier head body, a membrane adjacent to the pixel cartridge array, a controller coupled to the pixel cartridge array. The controller is configured to receive and orient a substrate such that the substrate is an oriented substrate, determine a thickness profile on the oriented substrate, position the oriented substrate in a loading position, receive the oriented substrate, and polish the oriented substrate use the pixel cartridge array. The pixel cartridge array is configured to apply pressure on a membrane of a carrier head in a chemical mechanical polishing system.

In yet another embodiment, a method of processing a substrate is provided. The method includes ding receiving and orienting a substrate such that the substrate is an oriented substrate, determining a thickness profile on the oriented substrate, positioning the oriented substrate in a loading position, receiving the oriented substrate, and polishing the oriented substrate using a pixel cartridge array, the pixel cartridge array configured to apply pressure on a membrane of a carrier head in a chemical mechanical polishing system.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments of the present disclosure and are therefore not to be considered limiting of its scope, as the present disclosure may admit to other equally effective embodiments.

FIG. 1 illustrates a schematic top view of a chemical mechanical polishing system, according to certain embodiments.

FIG. 2 illustrates a schematic sectional view of a polishing station, according to certain embodiments.

FIG. 3A illustrates a schematic, cross-sectional side view of a pad conditioner head, according to certain embodiments.

FIG. 3B illustrates a schematic, bottom view of the pad conditioner head of FIG. 3A, according to certain embodiments.

FIG. 3C illustrates a schematic, bottom view of the pad conditioner head of FIG. 3A, according to certain embodiments.

FIG. 4 illustrates a schematic, cross-sectional side view of a pixel cartridge, according to certain embodiments.

FIG. 5 illustrates a flow diagram for a method of planarizing a substrate, according to certain embodiments.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Embodiments of the present disclosure generally relate to semiconductor manufacturing. More specifically, the embodiments of the present disclosure generally relate to correcting thickness asymmetry of a substrate during chemical mechanical polishing.

Symmetric removal during chemical mechanical polishing (CMP) may problematic because a substrate having an asymmetrically non-uniform thickness profile will remain asymmetric after the CMP process is complete. For example, the asymmetric thickness of the substrate may result in the circuits formed on a surface of the substrate having a different RC time constant for the integrated circuits in devices formed on opposing sides of the same surface of the substrate, due to the ICs formed on the thinner edge of the substrate having less metal than the ICs formed on the thicker edge of the substrate. The resulting integrated circuits will have processing speeds that vary based on the corresponding substrate thickness. As such, precise, localized planarization is needed to remove excess material, e.g., areas of higher thickness, from the substrate.

The present disclosure provides for systems and methods to improve planarization of a substrate by improved localized planarization. Specifically, the present disclosure provides a carrier head including a pixel cartridge array configured to apply localized pressure to a membrane of the carrier head according to the angular position of the substrate. The angular position of the substrate is determined by a notch sensor array configured to determine the angular position of a notch in the substrate. The pressure applied by the pixel cartridge array varies depending on the region of the substrate to be planarized. The pixel cartridge array, in conjunction with the notch sensor array, allows for precise, local planarization of regions of the substrate as determined by recipe and substrate thickness.

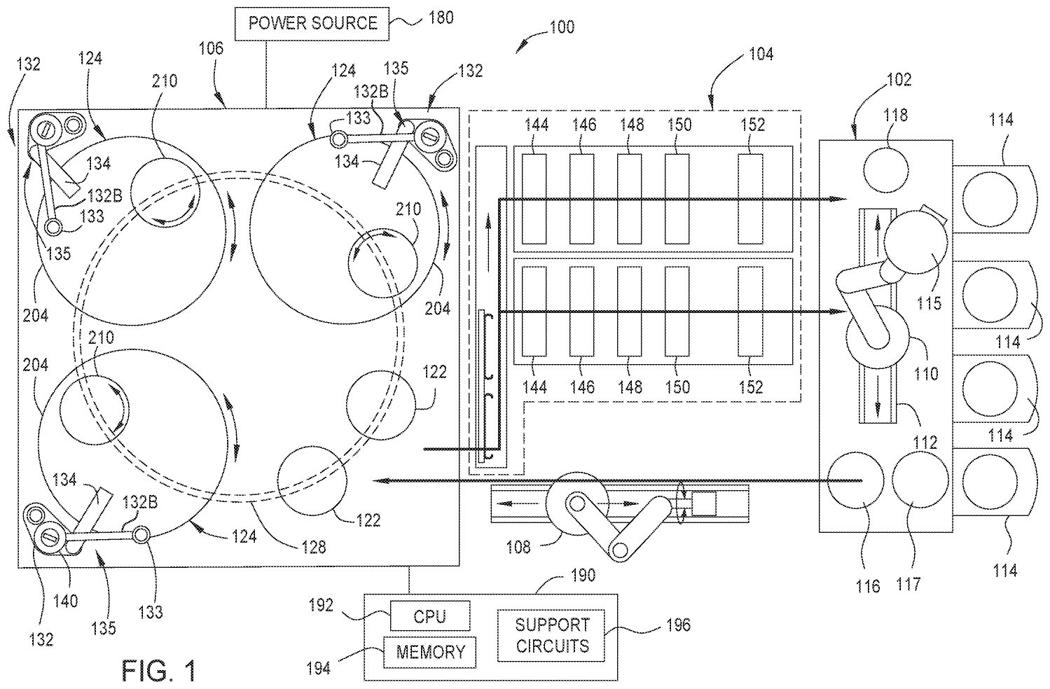

FIG. 1 is a top plan view illustrating one embodiment of a chemical mechanical polishing (CMP) system 100 that can be adapted to perform a polishing process on a substrate using a polishing pad described herein, which can be used to improve the polishing process results achieved on the substrate over conventional polishing processes. The CMP system 100 includes a factory interface module 102, a cleaner 104, and a polishing module 106. A wet robot 108 is provided to transfer substrates 115 between the factory interface module 102 and the polishing module 106. The wet robot 108 may also be configured to transfer the substrates 115 between the polishing module 106 and the cleaner 104. The factory interface module 102 includes a dry robot 110 which is configured to transfer the substrates 115 between one or more cassettes 114, one or more metrology stations 117, and one or more transfer platforms 116. In some embodiments, as shown in FIG. 1, four substrate storage cassettes 114 are shown. The dry robot 110 within the factory interface 102 has sufficient range of motion to facilitate transfer between the four cassettes 114 and the one or more transfer platforms 116. Optionally, the dry robot 110 may be mounted on a rail or track 112 to position the robot 110 laterally within the factory interface module 102. The dry robot 110 is also configured to receive the substrates 115 from the cleaner 104 and return the clean polished substrates to the substrate storage cassettes 114.

Still referring to FIG. 1, the polishing module 106 includes a plurality of polishing stations 124 on which the substrates 115 are polished while being retained in a carrier head 210. The polishing stations 124 are sized to interface with one or more carrier heads 210 so that polishing of a substrate 115 may occur in a single polishing station 124. The carrier heads 210 are coupled to a carriage (not shown) that is mounted to an overhead track 128 that is shown in phantom in FIG. 1. The overhead track 128 allows the carriage to be selectively positioned around the polishing module 106 which facilitates positioning of the carrier heads 210 selectively over the polishing stations 124 and load cup 122. In some embodiments, as shown in FIG. 1, the overhead track 128 has a circular configuration which allows the carriages retaining the carrier heads 210 to be selectively and independently rotated over and/or clear of the load cups 122 and the polishing stations 124.

In some embodiments, as shown in FIG. 1, three polishing stations 124 are shown located in the polishing module 106. At least one load cup 122 is in the corner of the polishing module 106 between the polishing stations 124 closest to the wet robot 108. The load cup 122 facilitates transfer between the wet robot 108 and the carrier heads 210.

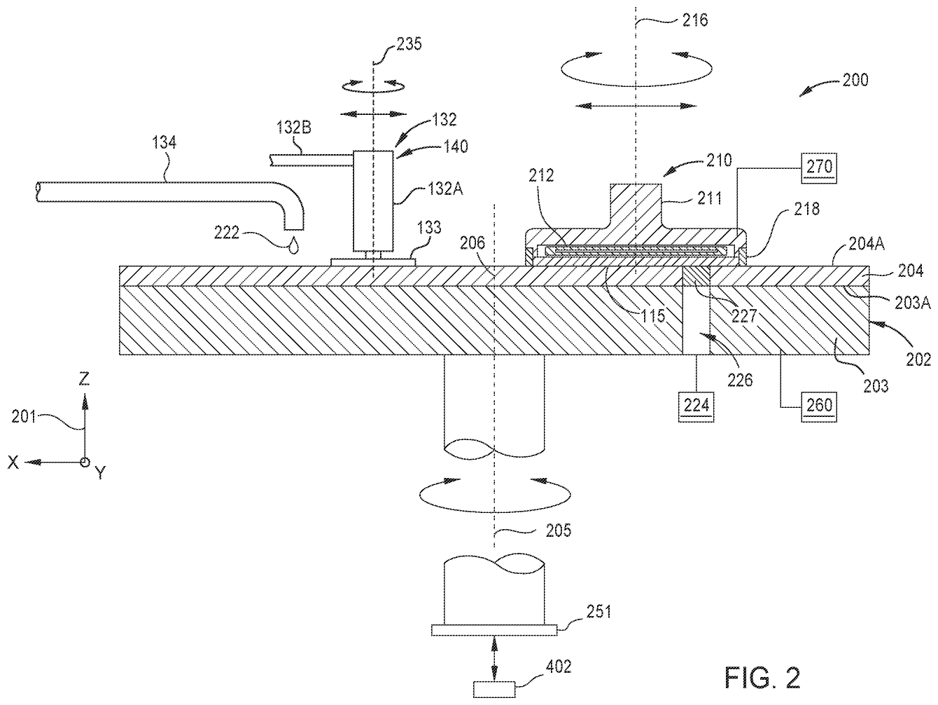

Each polishing station 124 includes a polishing pad 204 having a polishing surface (e.g., a polishing surface 204A in FIG. 2) capable of polishing a substrate 115. Each polishing station 124 includes one or more carrier heads 210, a conditioning assembly 132 and a polishing fluid delivery module 135. During the operation of the polishing assembly 200, the pad 204 is subject to compression, shear and friction, which produce heat and wear, as a slurry and substrate are urged against the polishing surface 204A by the one or more carrier heads 210. The slurry and abraded material from the substrate and pad are pressed into the surface and pores of the pad material, which causes the pad material, and pores formed in the pad material to become matted and even partially fused. These effects created at the polishing surface 204A are sometimes referred to as “glazing,” and reduce the pad's ability to have a desirable polishing rate and provide fresh slurry to the substrate during processing. In some embodiments, the conditioning assembly 132 may comprises a conditioning disk 133 of a pad conditioning assembly 140, which dresses the polishing surface of the polishing pad 204 by removing polishing debris, remove any “glazing” formed on the polishing pad 204, which occurs after extended use of the pad. Generally, the bottom surface of the conditioning disk 133 contacts and abrades the polishing surface 204A of the polishing pad 204 during a pad conditioning process. During a pad conditioning process, the arm 132B of the pad conditioning assembly 140, provides translational motion to the conditioning disk 133 so that the conditioning disk 133 may contact and abrade the entire polishing surface of the polishing pad 204. A typical pad conditioning process includes applying a down force to the conditioning disk 133 relative to the polishing surface 204A of the polishing pad 204 in a range between about 0.1 psi and about 30 psi, such as, between about 0.7 psi to about 2.0 psi, to achieve an down force of between about 3 and 6 pounds. During a pad conditioning process the conditioning disk 133 is rotated about the axis 235 at a rotation speed of typically between about 30 RPM to about 120 RPM, for example, between about 30 RPM to about 100 RPM, or even between about 40 RPM to about 70 RPM, while a rotational actuator causes the conditioning arm 132B to cause the conditioning disk 133 to translate across the polishing surface 204A of the polishing pad 204 as the polishing pad 204 is being rotated about the axis 216 at a rotation speed of typically between about 20 RPM to about 120 RPM, for example, between about 40 RPM to about 85 RPM. The abrasive action applied by the conditioning disk 133 to the surface of the polishing pad 204 will intentionally cause damage to the polishing layer material at the polishing surface 204A to assure that any “glazing” and other unwanted debris is removed. The pad conditioning process can also be used to open pores formed in the polishing pad 204, when they are present at or near in the polishing surface 204A.

Referring to FIG. 2, the conditioning disk 133 typically has a plurality of abrasive regions (not shown) on its lower face, in which abrasive particles (e.g., diamond or silicon carbide particles) are secured. The abrasive particles are disposed on a surface of a backing plate portion of the conditioning disk 133 to provide a structure capable of enabling the removal of the material on the polishing surface 204A of the polishing pad 204. The abrasive particles can be attached to the lower surface of the conditioning disk 133 by way of known electroplating and/or electrodeposition processes, or by way of organic binding, brazing or welding processes. Each individual abrasive particle can have one or more cutting points, ridges or mesas. In some configurations, the abrasive diamond particles are between 60 micrometers (μm) and 250 μm in size, which can provide superior conditioning of the material used in 3D printed polishing pads, e.g., a low wear rate while maintaining uniform surface roughness across the pad.

In other embodiments, the polishing fluid delivery module 135 may comprise a fluid delivery arm 134 to deliver a slurry. Each polishing station 124 comprises a pad conditioning assembly 132. In some embodiments, the fluid delivery arm 134 is configured to deliver a fluid stream (e.g., a fluid 222 in FIG. 2) to a polishing station 124. The polishing pad 204 is supported on a platen (e.g., a platen 202 in FIG. 2) which rotates the polishing surface during processing. The platen 202 includes a body 203 that has a pad supporting surface 203A. The CMP system 100 is coupled with a power source 180.

In some embodiments, the substrates 115, such as a silicon wafer having one or more layers deposited thereon, are loaded into the CMP system 100 via a cassette 114. During processing, the factory interface module 102 extracts the substrate 115 from the cassette 114 to begin processing while a controller 190 coordinates operations of the CMP system 100. The dry robot 110 within the factory interface module 102 then transfers the substrate 115 to the metrology station 117, which in some cases measures a thickness profile of the substrate 115. The dry robot 110 then transfers the substrate 115 to the transfer platforms 116, and the wet robot 108 transfers the substrates through subsequent processing components including the CMP system 100.

The substrate 115 is then transferred by the wet robot 108 to a load cup 122 so that a carrier head 210 can pick-up and transport the substrate 115 to each of the one or more polishing stations 124 to undergo a CMP process according to the polishing parameters selected. Each polishing station includes a polishing pad 204 secured to a rotatable platen 202. Different types of polishing pads 204 may be used at different polishing stations 124 to control the material removal of the substrate 115.

During CMP, the controller 190 controls aspects of the polishing stations 124. In some embodiments, the controller 190 is one or more programmable digital computers executing digital control software. The controller 190 can include a processor 192 situated near the polishing apparatus, e.g., a programmable computer, such as a personal computer. The controller can include a memory 194 and support circuits 196. The controller 190 can, for example, coordinate contact between the substrate 115 and the polishing pad 204 at differing rotational speeds such that a selective removal profile is aligned with indices of residue locations on the substrate 115, such as an asymmetric thickness profile of the substrate 115. Aligning these profiles ensures the thickest part of the substrate 115 has the most material removed and reduces the asymmetry of the substrate 115 during polishing. The controller 190 may include a plurality of separate controllers that are connected via network.

After polishing in at least one of the polishing stations 124, the carrier head 210 (FIG. 2) transports the substrate 115 to the load cup 122, and then the wet robot 108 transports the substrate 115 from the load cup 122 to a cleaning chamber in the cleaner 104, where slurry and other contaminants that have accumulated on the substrate surface during polishing are removed. In the embodiment depicted in FIG. 1, the cleaner 104 includes two pre-clean modules 144, two megasonic cleaner modules 146, two brush box modules 148, a spray jet module 150, and two dryers 152. The dry robot 110 then removes the substrate 115 from the cleaner 104 and transfers the substrate 115 to the metrology station 117 to be measured again. In certain embodiments, the post-polish layer measurements can be used to adjust the polishing process parameters for a subsequent substrate. Finally, the dry robot 110 returns the substrate 115 to one of the cassettes 114.

FIG. 2 depicts a schematic sectional view of a polishing station 124 of the CMP system 100 from FIG. 1 that comprises a polishing assembly 200 having a polishing pad 204 formed according to embodiments described herein. In particular, FIG. 2 shows how a carrier head 210 is positioned relative to the polishing pad 204. A coordinate system 201, having an x-axis, a y-axis, and a z-axis, shows the orientation of the different components of the polishing assembly 200 in this and subsequent figures. The coordinate system 201 shows positive directions of the x, y, and z-axes and positive direction for rotation about the z-axis, which is in a counter-clockwise direction. The opposite directions (not shown) are negative directions.

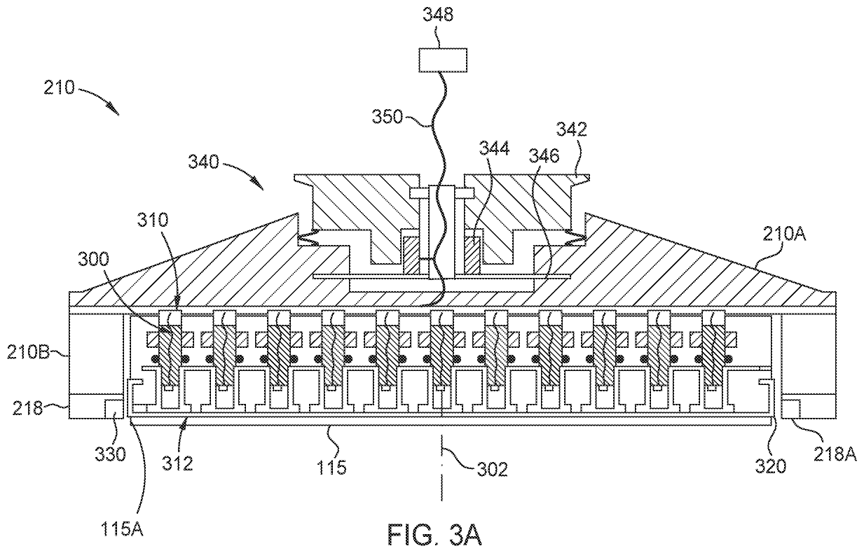

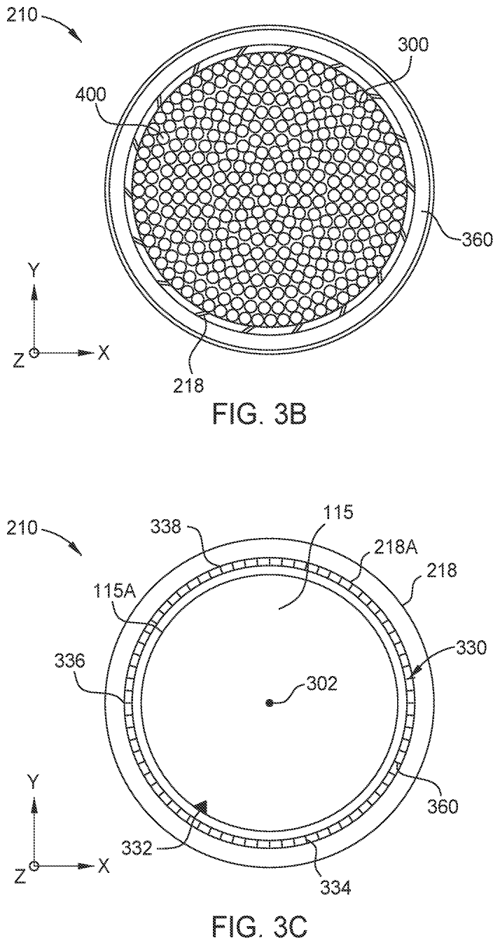

In some embodiments, the polishing pad 204 is secured to the pad supporting surface 203A of the platen 202 using an adhesive layer 220 (FIG. 3A), such as a pressure sensitive adhesive (PSA) layer, as shown in FIG. 3A, disposed between the polishing pad 204 and the pad supporting surface 203A of the platen 202. In some embodiments, the PSA layer can include a rubber resin, acrylic or silicone containing material.

The carrier head 210, facing the platen 202 and the polishing pad 204 mounted thereon, includes a flexible diaphragm 212 configured to impose different pressures in different regions of the flexible diaphragm 212 against a surface of a substrate 115 that is disposed between the carrier head 210 and the polishing pad 204. The carrier head 210 includes a carrier ring 218 surrounding the substrate 115, which holds the substrate in place. The carrier head 210 rotates about a carrier head axis 216 while the flexible diaphragm 212 urges a to-be-polished surface of the substrate 115, such as a device side of the substrate 115, against a polishing surface 204A of the polishing pad 204. During polishing, a downforce on the carrier ring 218 urges the carrier ring 218 against the polishing surface 204A to improve the polishing process uniformity and prevent the substrate 115 from slipping out from under the carrier head 210.

In some embodiments, the polishing pad 204 rotates about a platen axis 205. The polishing pad 204 has a polishing pad axis 206 that is typically collinear with the platen axis 205. In some embodiments, the polishing pad 204 rotates in the same rotational direction as the rotational direction of the carrier head 210. For example, the polishing pad 204 and carrier head 210 both rotate in a counter-clockwise direction. As shown in FIG. 2, the polishing pad 204 has a surface area that is greater than the to-be-polished surface area of the substrate 115. However, in some embodiments, the polishing pad 204 has a surface area that is less than the to-be-polished surface area of the substrate 115.

In some embodiments, an endpoint detection (EPD) system 224 detects reflected light that is directed towards the substrate 115 from a light source, through a platen opening 226 and an optically transparent window feature 227 of the polishing pad 204 disposed over the platen opening 226, and then back through these components to a detector (not shown) within the EPD system 224 during processing to detect properties of a layer formed on a surface of the substrate during polishing. The EPD system 224 can allow a thickness and/or residue location measurement, of the substrate 115 to be taken while the polishing assembly 200 is in use. In some embodiments, an eddy current probe is used to measure the thickness of conductive layers formed on a region of a surface of the substrate 115 by the comparison of the relative angle and position of the notch of the substrate 115, or carrier head 210, to the EPD system 224 within the platen 202.

During polishing, a fluid 222 is introduced to the polishing pad 204 through the fluid delivery arm 134 portion of the polishing fluid delivery module 135, which is positioned over the polishing surface 204A of the polishing pad 204. In some embodiments, the fluid 222 is a polishing fluid, a polishing slurry, a cleaning fluid, or a combination thereof. In some embodiments, the polishing fluid may include water based chemistries that include abrasive particles. The fluid 222 may also include a pH adjuster and/or chemically active components, such as an oxidizing agent, to enable CMP of the material surface of the substrate 115 in conjunction with the polishing pad 204. The fluid 222 removes material from the substrate as the carrier head 210 urges the substrate against the polishing pad 204.

FIG. 3A illustrates a schematic, cross-sectional side view of an embodiment of the carrier head 210 with the carrier ring carrier ring 218. FIG. 3B is a schematic, bottom view of the carrier head 210 with the carrier ring carrier ring 218. FIG. 3C is a schematic, bottom view of the carrier head 210 with a substrate mounted, e.g., substrate 115. As shown in FIG. 3A, the carrier head 210 includes a pixel cartridge array 300 disposed within a carrier head body 210A enclosed by sidewalls 210B and concentric to a head center axis 302. The pixel cartridge array 300 includes a cartridge top end 310 and a cartridge bottom end 312. The cartridge bottom end 312 is adjacent to and may contact a membrane 320. The membrane 320 is configured to contact the substrate 115 during polishing. The carrier ring 218, disposed adjacent to the cartridge bottom end 312, includes notch sensors 330 configured to detect the presence of a notch 332 (FIG. 3C) in the substrate 115. The notch sensors 330 may be disposed on an inner edge 218A of the carrier ring 218, adjacent to the membrane 320 and the substrate 115. The notch 332 is on an outer edge 115A of the substrate 115 and may be at least 1.25 mm deep into the substrate. The notch 332 may have any desired profile, e.g., as viewed from the top or bottom of the substrate 115, such as a triangular, rectangular, or circular profile, though the notch 332 is shown to have a triangular cross-sectional profile. The cross-sectional size and depth of the notch 332 is dependent on the type of notch sensors 330 used.

The carrier head 210 may also include a gimbal assembly 340 in an upper portion of the carrier head body 210A. The gimbal assembly 340 may include a spindle adaptor 342, electromagnet 344, and a flexure gimbal 346 each configured to actuate the carrier head 210 with respect to the head center axis 302, e.g., along the head center axis 302 or in a direction normal to the head center axis 302. The carrier head 210 may also include slip rings 348 to accommodate a coupling cable 350 which couples the pixel cartridge array 300 to the controller 190.

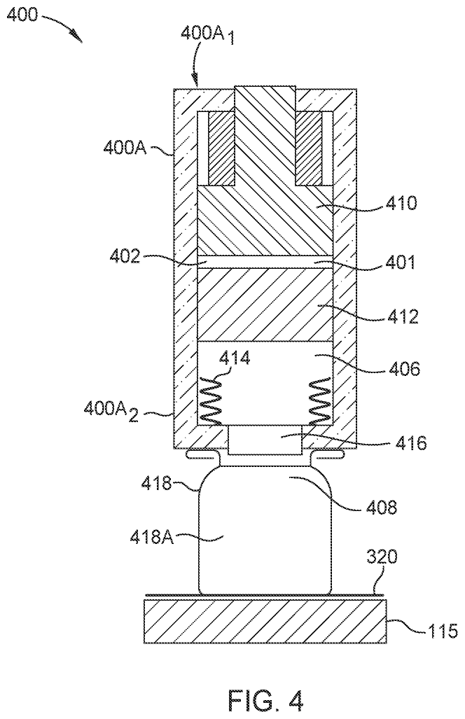

As shown in FIG. 3B, the pixel cartridge array 300 may be centered about the head center axis 302 and may expand an entire surface of the membrane 320. The pixel cartridge array 300 may include a circular array of pixel cartridges 400 (FIG. 4), such as about 100 pixel cartridges, such as 110, such as 120, or more. The pixel cartridge array 300 may be actuated by the controller 190 such that a portion or portions of the pixel cartridge array 300, exerts higher or lower pressure on the membrane 320. This allows for portions of the substrate 115 to be planarized more precisely.

As shown in FIG. 3C, the notch sensors 330 may be part of a notch sensor array 360 that is disposed on the inner edge 218A of the carrier ring 218. In operation, the substrate 115 may be mounted into or disposed over the membrane 320 and the pixel cartridge array 300. The substrate 115 includes a notch 332 on an outside edge 115A adjacent to the inner edge 218A of the carrier ring 218 and the notch sensor array 360. The notch 332 is placed into the substrate 115 at a predetermined angular position. This angular position is stored into the controller 190 and recalled during processing of the substrate 115. Each of the notch sensors 330 of the notch sensor array 360 may be coupled to the controller 190 and configured to detect the notch 332. For example, the notch sensors 330 may be capacitive sensors that continuously detect the notch 332 by emitting an electric field from a sensing end of the sensor and detecting disturbances, e.g., the notch 332, in the emitted electric field. The notch sensors 330, when configured as capacitive sensors, may detect the position of the notch 332 within +/−1 degree. As the substrate 115 rotates, the notch sensor array 360 detects if the notch 332 is present at a certain angular position, e.g., at a first notch sensor 334 of the notch sensor array 360, the pixel cartridge array 300 may be actuated according to a recipe stored in the controller 190. As the angular position changes, e.g., the notch 332 is detected at a second notch sensor 336 of the notch sensor array 360, the pixel cartridge array 300 is actuated to adjust for the angular position according to the recipe. Similarly, as the angular position changes again, e.g., the notch 332 is detected at a third notch sensor 338 of the notch sensor array 360, the pixel cartridge array 300 is actuated to adjust for the new angular position according to the recipe. The continuous monitoring and detection of the notch 332 of the substrate 115 allows the pixel cartridge array 300 to adjust pressure on the membrane 320, increasing or decreasing pressure on desired portions of the substrate 115, resulting in precise, local planarization of the substrate 115.

FIG. 4 illustrates a schematic, cross-sectional side view of a pixel cartridge 400, which may be used in the pixel cartridge array 300 as described above. The pixel cartridge 400 includes a cartridge body 400A, with a top portion 400A₁ and bottom portion 400A₂, and an inner volume 402 having an upper volume 404 and a lower volume 406. An electromagnet 410 is disposed within the inner volume 402 and defines a top end of the upper volume 404 with a permanent magnet 412 defining a bottom end of the upper volume 404. The permanent magnet 412 defines a top end of the lower volume 406 and the bottom portion 400A₂ defines a bottom end of the lower volume 406. A spring 414 is disposed within the lower volume 406 and may contact the permanent magnet 412. The bottom portion 400A₂ includes a through-hole 416 that fluidly couples the lower volume 406 to an inner balloon volume 418A of a balloon 418 connected to an outer surface of the bottom portion 400A₂. The lower volume 406 and the inner balloon volume 418A then define a gaseous volume 408. The gaseous volume 408 may include any suitable gas, such as air or nitrogen, and is sealed from the environment by the balloon 418 and the cartridge body 400A.

The electromagnet 410 is coupled to the controller 190 through the top portion 400A₁ by a coupling cable (not shown) on an end opposite the permanent magnet 412. In operation, the controller 190 energizes the electromagnet 410 to either attract or repulse the permanent magnet 412, changing the volume of the lower volume 406. As the gaseous volume 408 is constant, the change in the lower volume 406 results in an equal, but opposite, change in the inner balloon volume 418A. For example, if the electromagnet 410 is energized to repulse the permanent magnet 412, the lower volume 406 decreases, resulting in an increase in the inner balloon volume 418A, which expands the balloon 418 and applies increased localized pressure to the membrane 320. The added localized pressure to the membrane 320 is then conveyed to the substrate 115. Similarly, if the electromagnet 410 is energized to attract the permanent magnet 412, the lower volume 406 increases, creating a vacuum and resulting in a decrease in the inner balloon volume 418A, which contracts the balloon 418. The contraction of the balloon 418 reduces localized pressure to the membrane 320 and, subsequently, the substrate 115.

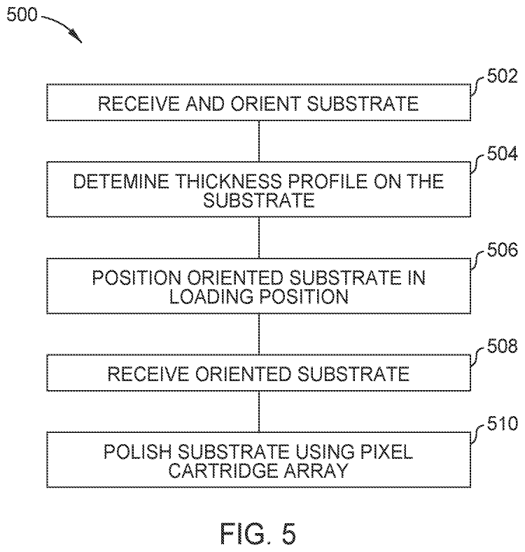

FIG. 5 illustrates a flow chart for an asymmetric polishing method 500 that can be performed in a polishing system, such as the CMP system 100 illustrated in FIG. 1. While the method described in relation to FIG. 5 primarily focuses on the operations used to perform an asymmetric polishing process, this shortened list of operations is not intended to be limiting as to the scope of the disclosure described herein since other polishing process operations may inserted before, during or after the operations discussed in relation to the asymmetric polishing method 500 without deviating from the basic scope of the disclosure provided herein. In one example, as briefly discussed above, one or more cleaning processes may be performed on a substrate in the cleaner 104 within the CMP system 100 after the asymmetric polishing method 500 has been performed on a substrate. In another example, one or more additional polishing processes (i.e., asymmetric polishing process or conventional symmetric polishing processes) may also be performed on a substrate on the same or a different polishing pad 204 within the CMP system 100 using the same carrier head 210 before or after performing the asymmetric polishing method 500.

At operation 502, a substrate 115 is removed from the cassette 114 by the dry robot 110 and positioned in the pre-aligner 118. The pre-aligner 118 is then used to determine the orientation of the substrate 115 by detecting one or more features formed on a surface of the substrate 115, such as the notch 332. The pre-aligner 118 then positions the substrate 115 in a desired angular orientation so that the dry robot 110 can then receive an oriented and pre-aligned substrate 115.

At operation 504, the oriented and pre-aligned substrate 115 is then removed from the pre-aligner 118 by the dry robot 110 and positioned in the metrology station 117. As discussed above, the metrology station 117, is then used to measure a thickness profile of the substrate 115 and determine the orientation of the thickness profile in relation to the one or more features formed on a surface of the substrate 115, such as the notch 332. During operation 504, the controller 190 receives the measurements and the orientation of the thickness profile from the metrology station 117. The controller 190 can then use the measurement and substrate orientation information to coordinate the asymmetric polishing processes performed in subsequent operations.

In some embodiments, operations 502 and 504 are performed in the same chamber, and thus a separate pre-aligner 118 may not be necessary since the metrology station 117 includes one or more substrate orientation detection elements.

At operation 506, the oriented, pre-aligned and thickness profile measured substrate 115 is then transferred by the dry robot 110 to a transfer platform 116, and the wet robot 108 then transfers the substrate 115 to a load cup 122. Based on the known orientation, alignment and thickness profile of the substrate 115, the substrate 115 is then positioned in a desired position and orientation in the load cup 122 so that a carrier head 210 can pick-up the substrate 115 in a known angular orientation. In some embodiments, the pre-alignment step(s) performed during operation 502 are configured to align and position the substrate 115 such that the subsequent transferring steps performed by the dry robot 110 and wet robot 108 cause the angular alignment of the substrate 115 to end up in a desired orientation in the load cup 122. The ability of the carrier head 210 to receive the substrate 115, having a known thickness profile, in a known and desirable orientation enables the subsequent asymmetric polishing process at operation 510 to be performed on the desired regions of the substrate 115 in one or more of the polishing stations 124.

At operation 508, the carrier head 210 then picks-up the oriented and aligned substrate 115 from its known position within the load cup 122 and transfers the substrate 115 to a surface 204A of a polishing pad 204 in a polishing station 124 so that the subsequent asymmetric polishing process at operation 510 can be performed. Prior to or during operation 508, one or more carrier head 210 orientation detecting elements are used to assure that the angular orientation of the carrier head 210 relative to the load cup 122 and position of the one or more features formed on a surface of the substrate 115, such as the notch 332, are known and oriented correctly. In some embodiments, the carrier head 210 includes an encoder, position flag or other orientation detecting element(s) that are coupled to an actuator (not shown), which when working together allows the carrier head 210 to be oriented in a known and desired angular orientation when it picks-up the aligned and oriented substrate 115 from the load cup 122.

At operation 510, the controller 190 then coordinates the relative motion of the carrier head 210 to the substrate 115 to perform the processing steps used to perform an asymmetric polishing process. For example, the notch sensors 330 of the notch sensor array 360 disposed on the carrier ring 218 send information to the controller 190 regarding the angular position of the notch 332 on the substrate 115. The controller 190 then actuates the desired pixel cartridge 400 of the pixel cartridge array 300, as determined by the thickness profile and recipe stored in the controller 190. For example, regions of higher thickness of the substrate 115 may require more pressure exerted on the membrane 320 by the pixel cartridge array 300 than regions of lower thickness. The controller 190 may then determine the amount and location of the pixel cartridge 400 relative to the pixel cartridge array 300 and the angular location from the notch 332. For example, the controller 190 may determine that a region of higher thickness on the substrate 115 requires a set of 10 pixel cartridges 400 to apply increased pressure at a region 180 degrees from the notch 332. The controller 190 may actuate the set of 10 pixel cartridges 400 to apply a uniform pressure in that region. Alternatively, the controller 190 may actuate the set of 10 pixel cartridges 400 to apply a non-uniform pressure, e.g. a gradient or other desired pressure profile, to the region. As the angular position of the substrate 115 changes relative to the carrier head 210, the controller 190 adjusts the pixel cartridge array 300 according to the recipe and the received position information from the notch sensor array 360 indicating the angular location of the notch 332.

The methods disclosed herein comprise one or more steps or actions for achieving the methods. The method steps and/or actions may be interchanged with one another without departing from the scope of the claims. In other words, unless a specific order of steps or actions is specified, the order and/or use of specific steps and/or actions may be modified without departing from the scope of the claims. Further, the various operations of methods described above may be performed by any suitable means capable of performing the corresponding functions. The means may include various hardware and/or software component(s) and/or module(s), including, but not limited to a circuit, an application specific integrated circuit (ASIC), or processor. Generally, where there are operations illustrated in figures, those operations may have corresponding counterpart means-plus-function components with similar numbering.

The present disclosure provides for systems and methods to improve planarization of a substrate by improved localized planarization. Specifically, the present disclosure provides a carrier head including a pixel cartridge array configured to apply localized pressure to a membrane of the carrier head according to the angular position of the substrate determined by a notch sensor array configured to determine the angular position of a notch in the substrate. The pressure applied by the pixel cartridge array varies depending on the region of the substrate to be planarized. The pixel cartridge array, in conjunction with the notch sensor array, allows for precise, local planarization of regions of the substrate as determined by recipe, substrate thickness, and location on the substrate.

When introducing elements of the present disclosure or exemplary aspects or embodiments thereof, the articles “a,” “an,” “the” and “said” are intended to mean that there are one or more of the elements.

The terms “comprising,” “including” and “having” are intended to be inclusive and mean that there may be additional elements other than the listed elements.

The term “coupled” is used herein to refer to the direct or indirect coupling between two objects. For example, if object A physically touches object B and object B touches object C, the objects A and C may still be considered coupled to one another-even if objects A and C do not directly physically touch each other. For instance, a first object may be coupled to a second object even though the first object is never directly in physical contact with the second object.

While the foregoing is directed to embodiments of the present disclosure, other and further embodiments of the disclosure may be devised without departing from the basic scope thereof, and the scope thereof is determined by the claims that follow.

What is claimed is:

1. A chemical mechanical polishing system, comprising:
a carrier head comprising a carrier head body, a pixel cartridge array disposed within the carrier head body, and a membrane adjacent to the pixel cartridge array;
a carrier ring configured to couple with the carrier head;
a notch sensor array disposed on the carrier ring; and
a controller coupled to the pixel cartridge array and the notch sensor array, the controller configured to:
(a) receive and orient a substrate such that the substrate is an oriented substrate;
(b) determine a thickness profile on the oriented substrate;
(c) position the oriented substrate in a loading position;
(d) receive the oriented substrate; and
(e) polish the oriented substrate use the pixel cartridge array, the pixel cartridge array configured to apply pressure on a membrane of a carrier head in a chemical mechanical polishing system.

2. The chemical mechanical polishing system of claim 1, wherein the pixel cartridge array comprises a plurality of pixel cartridges, each of the pixel cartridges comprising an electromagnet and a permanent magnet.

3. The chemical mechanical polishing system of claim 1, wherein polishing the oriented substrate comprises using the notch sensor array to determine an angular position of the oriented substrate using a notch in the oriented substrate.

4. The chemical mechanical polishing system of claim 1, wherein the pixel cartridge array is configured to apply pressure on the membrane based on the angular position of the oriented substrate.

5. The chemical mechanical polishing system of claim 1, wherein the pressure applied by the pixel cartridge array is adjusted based on the thickness profile on the oriented substrate.

6. The chemical mechanical polishing system of claim 1, wherein the pressure applied by the pixel cartridge array is non-uniform.

7. The chemical mechanical polishing system of claim 1, wherein the pixel cartridge array comprises at least 100 pixel cartridges.

8. A carrier head for chemical mechanical polishing, comprising:
a carrier head body configured to couple with a carrier ring;
a pixel cartridge array disposed within the carrier head body;
a membrane adjacent to the pixel cartridge array;
a controller coupled to the pixel cartridge array, the controller configured to:
(a) receive and orient a substrate such that the substrate is an oriented substrate;
(b) determine a thickness profile on the oriented substrate;
(c) position the oriented substrate in a loading position;
(d) receive the oriented substrate; and
(e) polish the oriented substrate use the pixel cartridge array, the pixel cartridge array configured to apply pressure on a membrane of a carrier head in a chemical mechanical polishing system.

9. The carrier head of claim 8, wherein the pixel cartridge array comprises a plurality of pixel cartridges, each of the pixel cartridges comprising an electromagnet and a permanent magnet.

10. The carrier head of claim 9, wherein polishing the oriented substrate comprises using the electromagnet of at least one of the pixel cartridges of the pixel cartridge array to apply pressure to the membrane based on the angular orientation of the substrate.

11. The carrier head of claim 8, wherein the pixel cartridge array is configured to apply pressure on the membrane based on the angular position of the oriented substrate.

12. The carrier head of claim 8, wherein the pressure applied by the pixel cartridge array is adjusted based on the thickness profile on the oriented substrate.

13. The carrier head of claim 8, wherein the pressure applied by the pixel cartridge array is non-uniform.

14. The carrier head of claim 8, wherein the pixel cartridge array comprises at least 100 pixel cartridges.

15. A method of processing a substrate, comprising:
(a) receiving and orienting a substrate such that the substrate is an oriented substrate;
(b) determining a thickness profile on the oriented substrate;
(c) positioning the oriented substrate in a loading position;
(d) receiving the oriented substrate; and
(e) polishing the oriented substrate using a pixel cartridge array, the pixel cartridge array configured to apply pressure on a membrane of a carrier head in a chemical mechanical polishing system.

16. The method of claim 15, wherein the pixel cartridge array comprises a plurality of pixel cartridges, each of the pixel cartridges comprising an electromagnet and a permanent magnet.

17. The method of claim 15, wherein polishing the oriented substrate comprises using a notch sensor array to determine an angular position of the oriented substrate using a notch in the oriented substrate.

18. The method of claim 15, wherein the pixel cartridge array is configured to apply pressure on the membrane based on the angular position of the oriented substrate.

19. The method of claim 15, wherein the pressure applied by the pixel cartridge array is adjusted based on the thickness profile on the oriented substrate.

20. The method of claim 15, wherein the pressure applied by the pixel cartridge array is non-uniform.
